(19) United States
(12) Patent Application Publication
(10) Pub. No.: US 2009/0115036 A1
(43) Pub. Date: May 7, 2009

(54) SEMICONDUCTOR CHIP PACKAGE HAVING METAL BUMP AND METHOD OF FABRICATING SAME

(75) Inventor: Seung-Woo SHIN, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/939,622

(22) Filed: Nov. 14, 2007

(30) Foreign Application Priority Data
Nov. 6, 2007 (KR) 2006-113995

(51) Int. Cl. H01L 23/495; H01L 21/60

(52) U.S. Cl. 257/673; 438/123; 257/E23.031; 257/E21.506

(57) ABSTRACT

A semiconductor chip package having a metal bump and related method of fabrication are provided. The semiconductor chip package includes first and second bonding pads separated on a substrate, an insulating layer from on the substrate with first and second openings respectively exposing the first and second bonding pads, and an oxidation preventing pattern formed from a nickel layer and a silver layer and formed on the first and second bonding pads.

### CROSS-REFERENCE TO RELATED APPLICATION

This application claims the benefit of Korean Patent Application No. 2006-113995, filed Nov. 17, 2006, the subject matter of which is hereby incorporated by reference.

### BACKGROUND OF THE INVENTION

1. Field of the Invention

The present invention relates to a semiconductor chip package and a method of fabricating same. More particularly, the invention relates to a semiconductor chip package having a metal bump and a method of fabricating same.

2. Description of Related Art

As the overall size of contemporary integrated circuits (ICs) has been reduced over time, the number of leads connecting the typical IC package has actually increased. Many different approaches have been taken to the problem of increasing the number of connection leads available on a shrinking IC package. For example, an IC package carrier has been designed to include a pin grid array (PGA). While the PGA carrier allows many lead connections to a relatively small carrier, the pins or leads may be easily broken. Additionally, in many applications, the PGA carrier has reached its integration density limit.

The ball grid array (BGA) generally improved upon the PGA. The BGA is integrated with an IC packaging substrate and allow highly dense collections of lead pins using a fine solder ball configuration. For this reason, BGA substrates are commonly used in the packaging of contemporary semiconductor chips.

Figures (FIGS.) 1A and 1B are schematic cross-sectional views illustrating a method of fabricating a conventional BGA package.

Referring to FIG. 1A, circuit patterns 12 are formed on a first surface of a substrate 10 and a second surface opposite to the first surface. A photo solder resist 14 covering the substrate having the circuit patterns 12 is formed. The photo solder resist 14 is patterned to form openings 16, which expose some circuit patterns of the circuit patterns 12. The circuit patterns exposed through the openings 16 serve as bonding pads. The bonding pads correspond to bond fingers 18 electrically connected to a semiconductor chip to be formed in a subsequent process, and solder pads 20 to which solder balls to be formed in a subsequent process are connected. The bonding pads are commonly formed of copper.

Then, to prevent formation of a natural oxide layer on the bonding pads, a nickel (Ni) layer 22 and a gold (Au) layer 24, which are sequentially stacked, are formed on bond fingers 18. Likewise, organic solderability preservatives (OSPs) 26 are formed on solder pads 20. Ni layer 22 and Au layer 24 are plating layers.

A semiconductor chip 28 is mounted on photo solder resist 14. Bond fingers 18 and semiconductor chip 28 are electrically connected to each other by bonding wires 30 configured by a wire bonding process.

Referring to FIG. 1B, a post-flex (not illustrated) having a defined viscosity is applied on solder pads 20 with OSPs 26. The post-flex contains alcohol and/or acidic components capable of permeating OSPs 26. Following application of the post-flex, OSPs 26 on solder pads 20 are removed using a high temperature treatment accompanied by a hardening process. A solder ball 32, which is referred to as “a bump”, is formed on solder pads 20 from which OSPs 26 have been removed.

A sealing resin 34 such as an epoxy molding compound (EMC) is formed on the substrate to cover semiconductor chip 28.

Despite the fact that that OSPs 26 have been at least partially removed to form solder ball 32 in the conventional BGA package, OSPs may still remain on solder pads 20. Thus, some residual OSPs may be interposed between solder pad 20 and solder ball 32. Such residual OSPs may cause deterioration in the performance characteristics of the interface between solder pad 20 and solder ball 32. That is, the residual OSPs decrease solderability between solder pad 20 and solder ball 32. Also, during the formation of solder ball 32 on a solder pad 20 contaminated by residual OSPs, a void may occur.

This is but one example of the remedial processes applied in conventional packaging to address the formation of natural oxide layers on bond pads. Indeed, many different materials and preparation techniques are applied to the bond fingers and/or solder pads in order to prevent a natural oxide layer from forming. The Ni and Au layers sequentially stacked on the bond finger, and the OSPs formed on the solder pad are just ready examples. Unfortunately, the fabrication throughput for IC packages is impaired with each additional remedial process applied to suppress the formation of natural oxide layers on bonding pads.

### SUMMARY OF THE INVENTION

Embodiments of the invention provide a semiconductor chip package having a metal bump with improved solderability. Embodiments of the invention also provide a method of fabricating a semiconductor chip package having improved throughput.

In one embodiment, the invention provides a semiconductor chip package, comprising; first and second bonding pads separated on a substrate, an insulating layer formed on the substrate with first and second openings respectively exposing the first and second bonding pads, and an oxidation preventing pattern formed from a nickel layer and a silver layer and formed on the first and second bonding pads.

In another embodiment, the invention provides a method of fabricating a semiconductor chip package, comprising; preparing a substrate with first conductive patterns disposed on first and second primary surfaces of the substrate, forming a second conductive pattern on the first conductive patterns, forming first bonding pads on the first surface of the substrate, and forming second bonding pads on the second surface of the substrate, forming and patterning an insulating layer on the substrate with first and second openings passing respectively exposing the first and second bonding pads, and forming an oxidation preventing pattern from a nickel layer and a silver layer on the first and second bonding pads.

### BRIEF DESCRIPTION OF THE DRAWINGS

FIGS. 1A and 1B are schematic cross-sectional views illustrating a method of fabricating a conventional BGA package.

FIGS. 2A to 2I are cross-sectional views illustrating a method of fabricating a semiconductor chip package according to an embodiment of the invention.

FIGS. 3 and 4 are enlarged cross-sectional views of regions “A” and “B” indicated in FIG. 2G, respectively.

FIG. 5 is a cross-sectional view of a semiconductor chip package according to another embodiment of the invention.

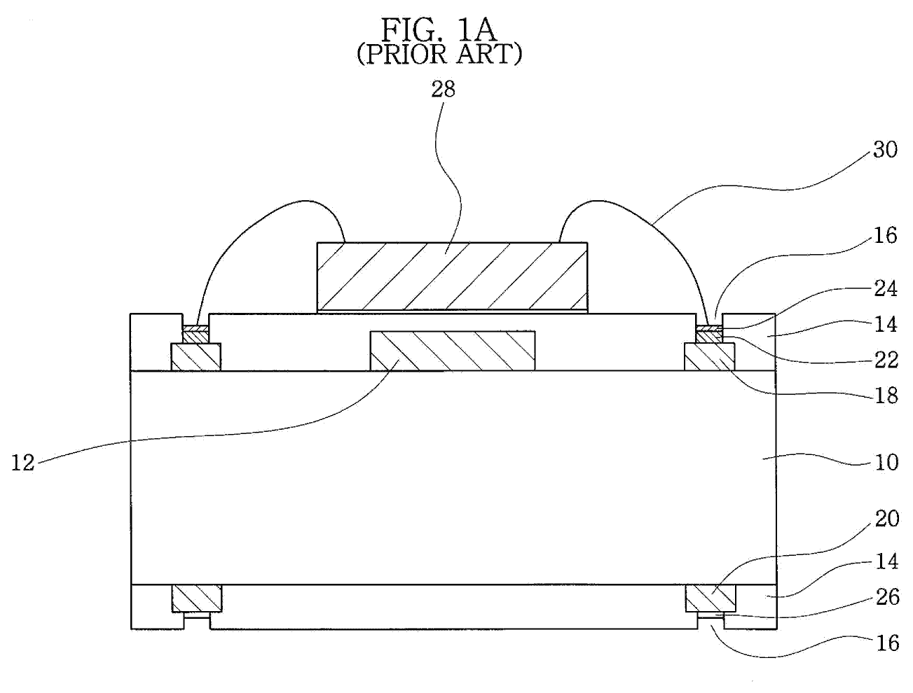

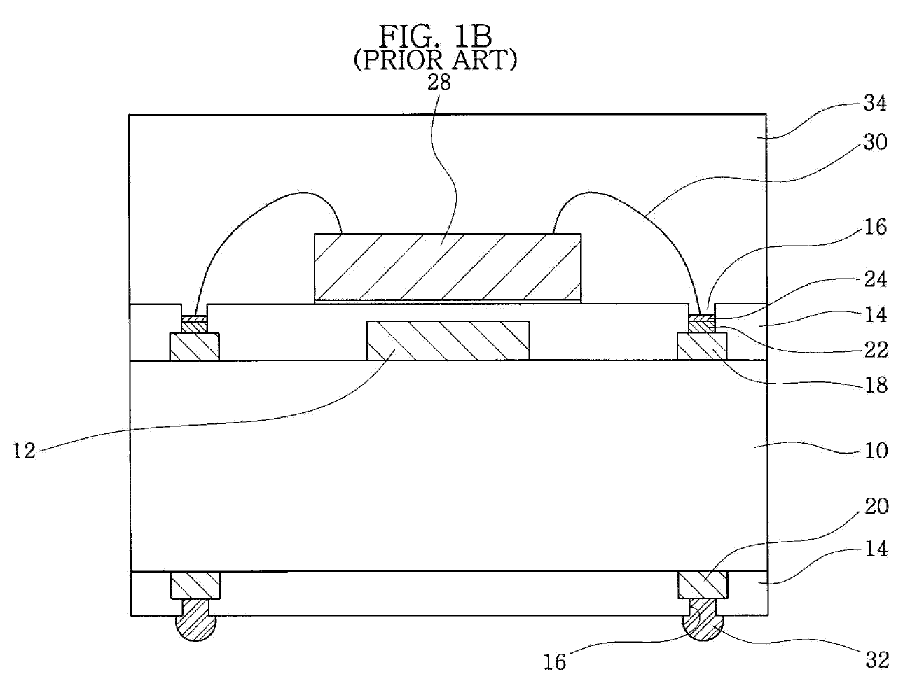

### DESCRIPTION OF EMBODIMENTS

The invention will now be described in some additional detail in the context of several exemplary embodiments illustrated in the accompanying drawings. This invention may, however, be embodied in different forms and should not be construed as being limited to only the illustrated embodiments. Rather, these embodiments are presented as teaching examples.

In the drawings, the thicknesses of various layers and regions may be exaggerated for clarity. Throughout the drawings and written description, like reference numerals are used to indicate like or similar elements.

In the written description that follows, when a layer is described to be formed “on” another layer or substrate, said layer may be formed directly on the other layer or substrate, or one or more intervening layers may be present between the layer and the other layer or substrate.

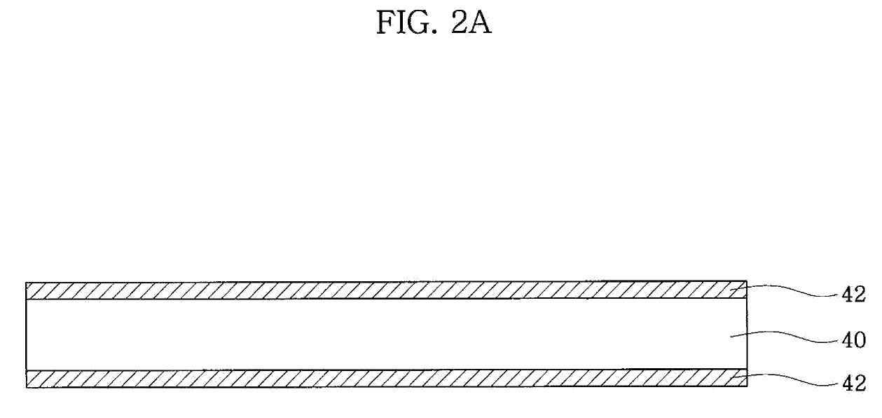

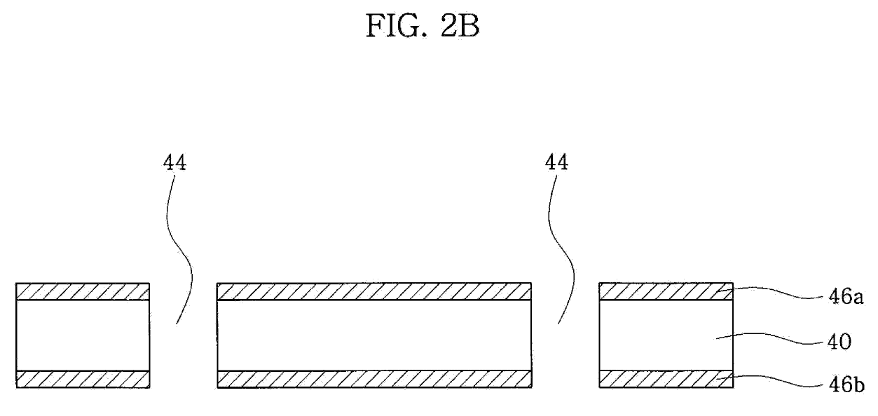

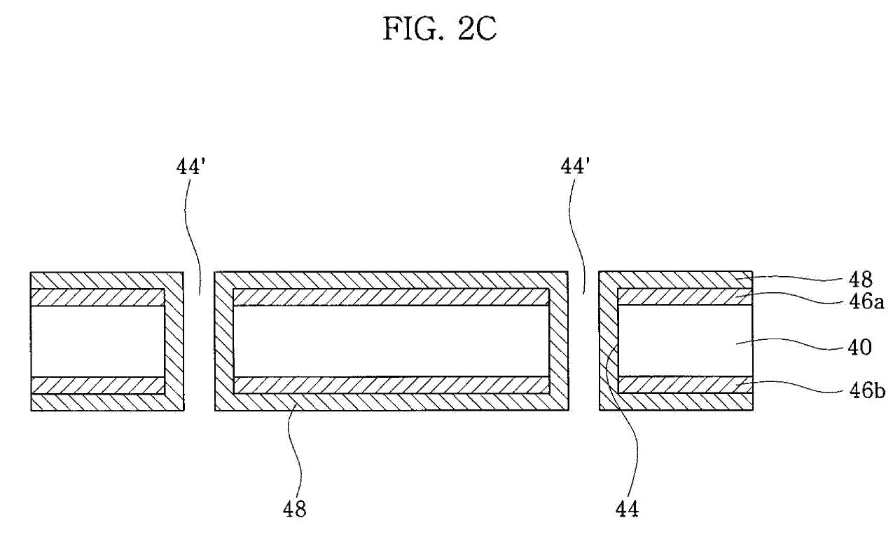

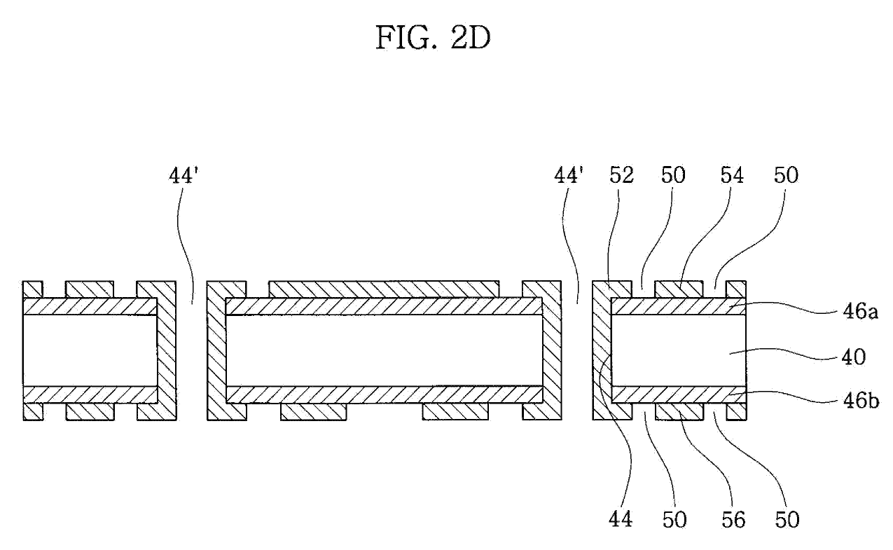

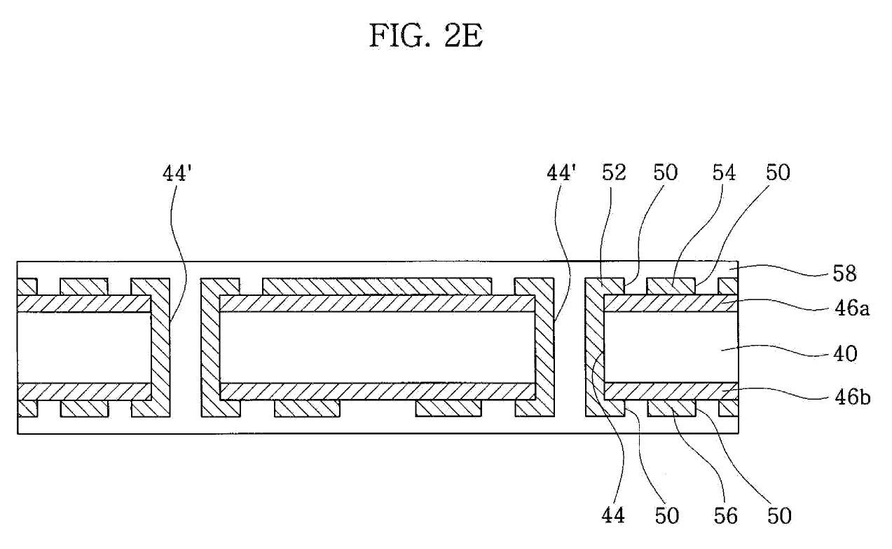

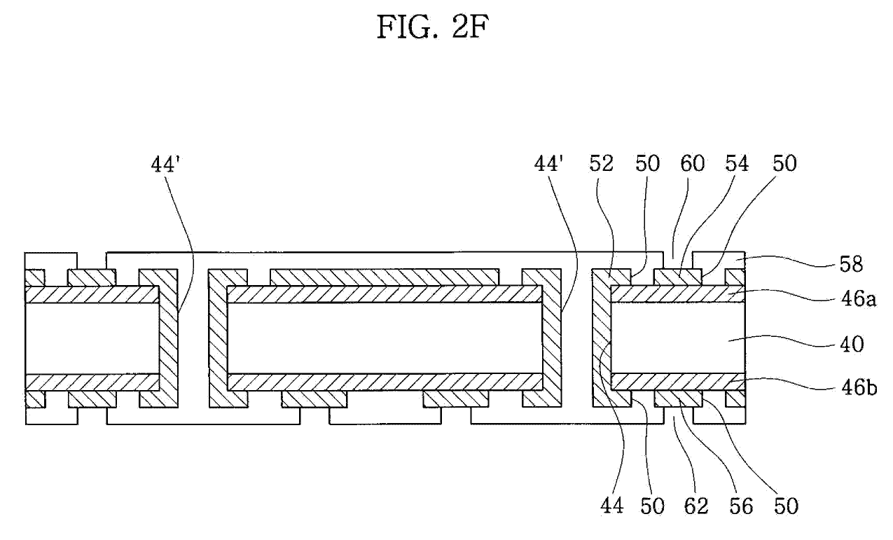

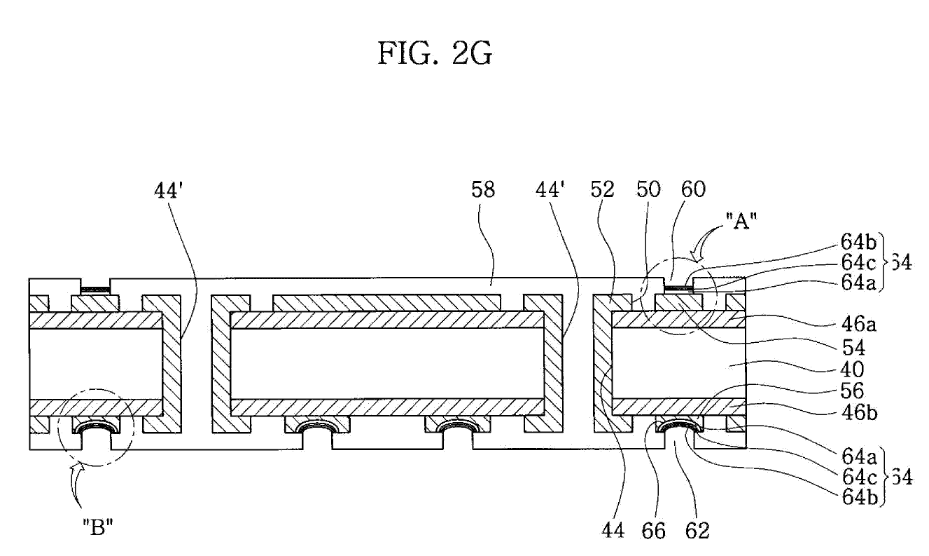

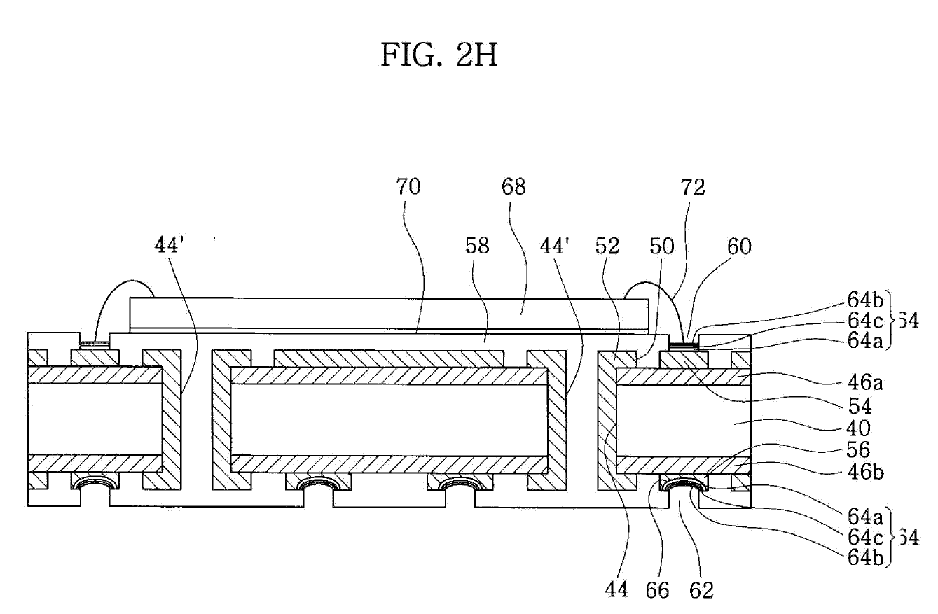

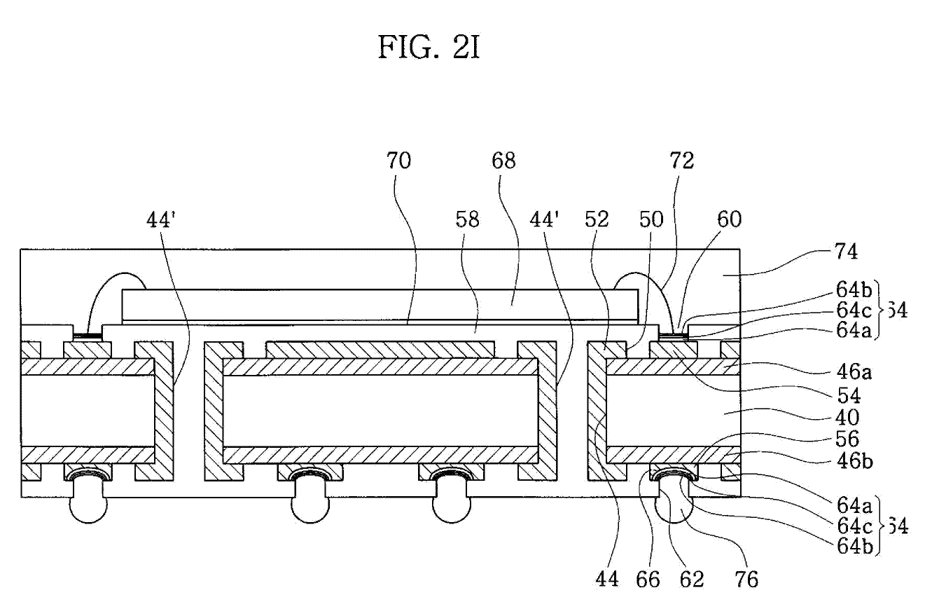

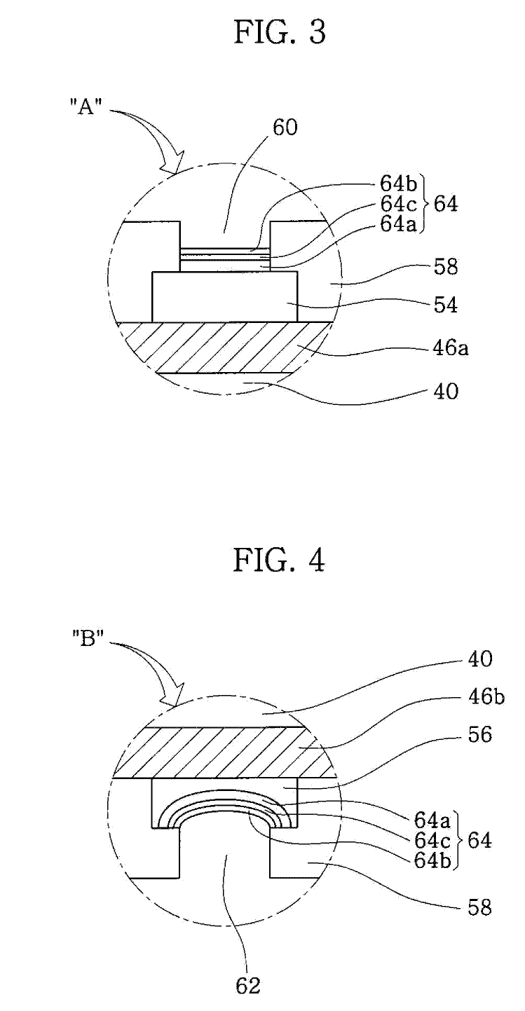

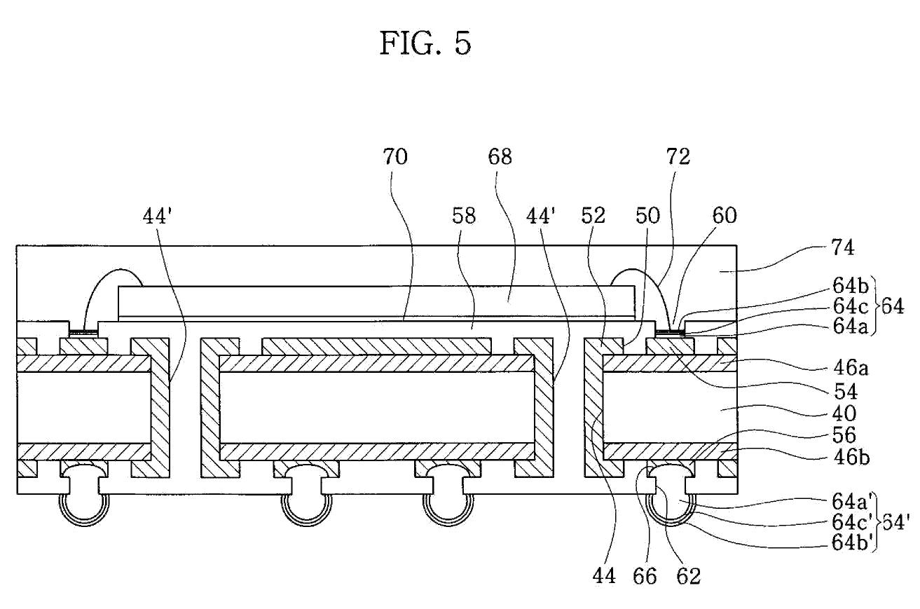

FIGS. 2A through 2I are cross-sectional views illustrating a method of fabricating a semiconductor chip package according to an embodiment of the invention. FIGS. 3 and 4 are enlarged cross-sectional views of regions “A” and “B” indicated in FIG. 2G, respectively. FIG. 5 is a cross-sectional view of a semiconductor chip package according to another embodiment of the invention.

Referring to FIG. 2A, a method of fabricating a semiconductor chip package according to an embodiment of the invention comprises preparing a substrate 40. Substrate 40 may be formed from an insulating material such as a reinforcing material infiltrated with an epoxy resin. In the illustrated example, substrate 40 may be formed from one of the FR-1 to FR-5 grade reinforcing materials conforming to the standards of National Electrical Manufacturers Association (NEMA). Alternately, substrate 40 may be formed from a semiconductor material such as silicon.

A first conductive layer 42 is formed on both opposing primary surfaces of substrate 40. First conductive layer 42 may be formed from a metal thin film such as a copper thin film.

Referring to FIG. 2B, both top and bottom sections of first conductive layer 42 along with substrate 40 may now be sequentially patterned to form via holes 44 passing through both first conductive layers 42 and substrate 40. Thus, first conductive patterns 46a and 46b are formed on primary surfaces of substrate 40 with the formation of via holes 44. In one embodiment, via holes 44 are formed using a laser beam.

Referring to FIG. 2C, a second conductive layer 48 is now formed on substrate 40 to cover via holes 44 and first conductive patterns 46a and 46b. Second conductive layer 48 may be formed of a metal layer such as a copper layer. In one possible embodiment, second conductive layer 48 may be formed using a conventional plating process. Accordingly, second conductive layer 48 may be formed on the sidewalls of via holes 44 to yield plated via holes 44′. (However, fabrication processes other than plating may be used to form, so-called “plated via holes 44′). Plated via holes 44′ will have a smaller diameter than via holes 44.

In a case where second conductive layer 48 is formed by a plating layer, and recognizing that the sidewalls of via holes 44 expose the material forming substrate 40, i.e., an insulating material, it is possible that second conductive layer 48 may not be formed properly within via holes 44. Therefore, second conductive layer 48, as formed on the sidewalls of via holes 44, may be formed from an electrode-less plating layer having a small thickness, followed by an electroplating layer having a greater thickness. Alternately, second conductive layer 48 may be formed by sputtering or chemical vapor deposition (CVD).

Referring to FIG. 2D, second conductive layer 48 may be patterned to form a plurality of openings 50 selectively exposing the surface of first conductive patterns 46a and 46b and second conductive patterns 52. In this manner, predetermined circuit patterns may be formed on substrate 40. Such circuit patterns are formed from a combination of second conductive patterns 52 and subsequently formed bonding pads. In the illustrated example, second conductive patterns 52 are formed proximate plated via holes 44′, and may thus serve to electrically connect first conductive patterns 46a and 46b. The resulting bonding pads include bond fingers 54 formed on a first primary (top) surface of substrate 40, and solder pads 56 formed on a second opposing primary (bottom) surface of substrate 40. In this particular example, bond fingers 54 and solder pads 56 may be formed to electrically connect to first conductive patterns 46a and 46b. Bond fingers 54 and solder pads 56 may thus be formed in a spaced apart arrangement defined by the geometry of second conductive patterns 52.

Bond fingers 54 will be electrically connected to a semiconductor chip in a subsequently applied process. Likewise, solder pads 56 may be electrically connected to solder balls by subsequently applied processes.

The patterning of second conductive layer 48 may further include coating a photoresist layer on second conductive layer 48, and forming photoresist patterns by patterning the photoresist layer. Second conductive layer 48 may be etched using the photoresist patterns as an etch mask to form second conductive patterns 52 and the bonding pads.

Referring to FIGS. 2E and 2F, an insulating layer 58 is formed on substrate 40 following formation of the predetermined circuit patterns. Insulating layer 58 may be formed from a photo solder resist. Insulating layer 58 may then be patterned to form first and second openings 60 and 62 selectively exposing bond fingers 54 and solder pads 56, respectively. In one possible embodiment, the patterning of insulating layer 58 may include selectively etching insulating layer 58. Thus, the top surfaces of bond fingers 54 and solder pads 56 may be partially exposed through first and second openings 60 and 62, respectively.

Referring to FIGS. 2G, 3, and 4, oxidation preventing pattern 64 filling (or partially filing) first and second openings 60 and 62 is formed. Oxidation preventing pattern 64 may be formed in lower regions of first and second openings 60 and 62 in contact with the exposed upper surfaces of bond fingers 54 and solder pads 56. Accordingly, oxidation preventing pattern 64 will prevent the formation natural oxide layer(s) on bond fingers 54 and solder pads 56 when exposed to the ambient environment through first and second openings 60 and 62.

In one embodiment, oxidation preventing pattern 64 is formed from a stacked combination of a nickel (Ni) layer 64a and a silver (Ag) layer 64b. The lower regions of first and second openings 60 and 62 may be filled (or partially filled) by oxidation preventing pattern 64 formed from similar materials. Thus, the throughput of semiconductor packages incorporating oxidation preventing pattern 64 may be facilitated by the use of a single process.

In the foregoing example, Ni layer 64a may be formed thicker than Ag layer 64b. Alternately, oxidation preventing pattern 64 may be formed from Ni layer 64a, Ag layer 64b, with a tin (Sn) layer 64c interposed therebetween.

Oxidation preventing pattern 64 may be formed using a plating technique, a sputtering process or CVD process.

Before the formation of oxidation preventing pattern 64 to partially fill second opening 62, solder pads 56 may be partially etched to form recessed solder pads 66. In the illustrated example, recessed solder pads 66 are formed with a concaved facing shape. When recessed solder pads 66 are subsequently covered by oxidation preventing pattern 64, the oxidation preventing pattern will conformally in-fill in the concaved shape of recessed solder pads 66. In this manner, recessed solder pads 66 may relatively increase a contact region between subsequently formed solder balls, thereby increasing the solderability between recessed solder pads 56 and the solder balls. This improved solderability results in greater immunity to mechanical shocks and improved overall reliability of the resulting solder ball structures.

Referring to FIG. 2H, a semiconductor chip 68 is mounted on insulating layer 58. In the illustrated example, semiconductor chip 68 is bonded to insulating layer 58 using a bonding agent 70. Additionally, bonding wires 72 may be used to electrically connect bond fingers 54 with semiconductor chip 68. In one embodiment, bonding wires 72 are formed from gold.

Referring to FIG. 2I, a sealing resin 74 is formed on substrate 40 once semiconductor chip 68 is bonded and electrically connected to bond fingers 54. Sealing resin 74 may be formed from an insulating epoxy resin or an insulating silicon resin.

Furthermore, solder balls 76 filling the second openings 62 and provided on oxidation preventing pattern 64 may be formed. In this case, solder balls 76 may be formed to project outward from second openings 62. The package having solder balls formed on solder pads 56 may then be thermally treated to better bond the solder balls to solder pads 56. The thermal treatment process may be performed using an IR reflow process for about 30 seconds at a temperature ranging between about 230 to 260° C.

Here, when solder balls 76 are formed of Sn, Ag, and Ni, respective metal layers 64a, 64b and 64c forming oxidation preventing pattern 64 may melt during the thermal treatment, thereby combining with solder balls 76. Thus, when the melted solder balls are solidified after the thermal treatment process, solder balls 76 and oxidation prevention pattern 64 formed a continuous conductive material having excellent strength. Furthermore, the solderability of the resulting solder balls is increased by improving an interface characteristic between solder pads 56 and the solidified solder balls.

Another embodiment of the invention is illustrated FIG. 5. Referring to FIG. 5, recessed solder pad 66 and second openings 62 are filled with a Ni layer 64a′. Ni layer 64a′ fills second opening 62 such that it extends outward in the general shape of a connection bump. Thereafter, Sn layer 64c′ and Ag layer 64b′ are sequentially formed on Ni layer 64a′. Thus, the resulting solder ball incorporates Ni layer 64a′ covered by Sn layer 64c′ and Ag layer 64b′. This particular arrangement may be beneficially used when substrate 40 is formed from a semiconductor material, such as silicon.

Thus, in the embodiment illustrated in FIG. 5, as compared with the embodiment illustrated in FIG. 2I, oxidation preventing pattern 64′ is formed from one or more Ni layers 64a′ (or Ni alloy layers), covered by at least Ag layer 64b′ (or a Ag alloy layer). Here, Ni layers 64a′ will be thicker than Ag layers 64b′. Alternately, oxidation preventing patterns 64 may be formed with Sn layer 64c′ (or a Sn alloy layer) interposed between Ni layers 64a′ and Ag layers 64b′. Any one or all of Ni layers 64a′, Ag layers 64b′, and Sn layers 64c′ may be formed by a plating process.

As another alternative, recessed solder pad 66 and second openings 62 may be filled with one or more copper layers instead of nickel. In such a case, one or more Ni, Sn, and/or Ag layers may be conformally formed on the projecting copper layers.

According to the foregoing embodiments of the invention, in order to suppress the formation of native oxide layers on a bonding pad, a Ni layer (or a Cu layer) and an Ag layer may be sequentially stacked and interposed between the bonding pad and a corresponding solder ball. Accordingly, an interface characteristic between the bonding pad and solder ball are improved, and solderability of the solder ball is also improved.

Also, since a bond finger and the oxidation preventing layer formed on the bonding pad such as a solder pad are formed of the same material, the oxidation preventing layer may be formed via a single process. Thus, throughput of a semiconductor chip package may be increased.

Exemplary embodiments of the invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the scope of the invention as set forth in the following claims.

What is claimed is:

1. A semiconductor chip package, comprising:
first and second bonding pads separated on a substrate;
an insulating layer from on the substrate with first and second openings respectively exposing the first and second bonding pads; and
an oxidation preventing pattern formed from a nickel layer and a silver layer and formed on the first and second bonding pads.

2. The semiconductor chip package according to claim 1, wherein the second bonding pad is a recessed bonding pad having a concaved facing surface on which the oxidation preventing pattern is formed.

3. The semiconductor chip package according to claim 2, further comprising a solder ball filling the second opening and formed on the oxidation preventing pattern.

4. The semiconductor chip package according to claim 3, wherein the solder ball comprises tin, silver and copper.

5. The semiconductor chip package according to claim 2, wherein the nickel layer essentially fills the concaved facing surface and the second opening to extend outward.

6. The semiconductor chip package according to claim 1, wherein the first and second bonding pads are formed from copper.

7. The semiconductor chip package according to claim 1, further comprising a tin layer interposed between the nickel layer and the silver layer.

8. The semiconductor chip package according to claim 1, further comprising:
first conductive patterns disposed on opposing primary surfaces of the substrate, wherein the first and second bonding pads are disposed on the first conductive patterns; and
a second conductive pattern electrically connecting the first conductive patterns.

9. The semiconductor chip package according to claim 8, wherein the second bonding pad is a recessed bonding pad having a concaved facing surface on which the oxidation preventing pattern is formed.

10. The semiconductor chip package according to claim 8, further comprising:
a semiconductor chip disposed on the insulating layer; and
a bonding wire electrically connecting the semiconductor chip to the first bonding pad.

11. A method of fabricating a semiconductor chip package, comprising:
preparing a substrate with first conductive patterns disposed on first and second primary surfaces of the substrate;
forming a second conductive pattern on the first conductive patterns;
forming first bonding pads on the first surface of the substrate, and forming second bonding pads on the second surface of the substrate;
forming and patterning an insulating layer on the substrate with first and second openings passing respectively exposing the first and second bonding pads; and
forming an oxidation preventing pattern from a nickel layer and a silver layer on the first and second bonding pads.

12. The method according to claim 11, further comprising:
partially etching the second bonding pad to form a concaved facing surface before formation of the oxidation preventing pattern.

13. The method according to claim 12, further comprising:
forming a solder ball on the oxidation preventing layer to fill the second opening.

14. The method according to claim 13, wherein the solder ball is formed of tin, silver, and copper.

15. The method according to claim 11, wherein the nickel layer is formed to fill the second opening to extend outward.

16. The method according to claim 11, wherein the first and second bonding pads are formed from copper.

17. The method according to claim 11, further comprising forming a tin layer disposed between the nickel layer and the silver layer.

18. The method according to claim 11, further comprising:
mounting a semiconductor chip on the insulating layer; and
forming a bonding wire to electrically connect the semiconductor chip to the first bonding pad.
